(19) United States
(12) Patent Application Publication
(10) Pub. No.: US 2009/0108850 A1
(43) Pub. Date: Apr. 30, 2009

(54) Insulation resistance decrease detector for industrial vehicle

(76) Inventors: Tomohiro Yamagami, Kariya-shi (JP); Shoichi Ieoka, Kariya-shi (JP)

Correspondence Address: Locke Lord Bissell & Liddell LLP;Attn: IP Docketing, Three World Financial Center, New York, NY, 10281-2101, US

(21) Appl. No.: 12/286,206

(22) Filed: Sep. 29, 2008

(30) Foreign Application Priority Data
Oct. 1, 2007 (JP) 2007-257644

(51) Int. Cl. G01R 31/02

(52) U.S. Cl. 324/551

(57) ABSTRACT

An insulation resistance decrease detector for an industrial vehicle is disclosed. The detector includes a coupling capacitor, a sensing resistor, an AC voltage applying section having a first terminal and a second terminal, a voltage detecting section, and a determining section. The AC voltage applying section applies an AC voltage of a predetermined frequency to the vehicle body through the sensing resistor and the coupling capacitor. The voltage detecting section detects the voltage at a node between the sensing resistor and the coupling capacitor. The determining section determines that a resistance value of the insulation resistor has decreased when the level of voltage detected by the voltage detecting section becomes less than or equal to a predetermined level.

### FIELD OF THE INVENTION

The present invention relates to an insulation resistance decrease detector for an industrial vehicle, and more specifically, to an insulation resistance decrease detector for an industrial vehicle including a high voltage circuit that supplies electricity to a drive motor for driving wheels or to a hydraulic pump.

### BACKGROUND OF THE INVENTION

For the purpose of electric shock prevention, vehicles such as hybrid vehicles having a high voltage circuit include an insulation resistance decrease detector for detecting that the high voltage circuit is short-circuited with the vehicle body, or that there is a leakage of electricity.

FIG. 4 shows a high voltage circuit 53 that includes a battery 52 for supplying electricity to a high voltage load 51. The high voltage circuit 53 is connected to a vehicle body 54 with an insulation resistor 55. The high voltage load 51 is, for example, a drive motor for drive wheels. Since the insulation resistor 55 has a resistance value of 2 to 3 MΩ, the high voltage circuit 53 is electrically insulated from a vehicle body 54. Reference numeral “56” denotes parasitic capacitance.

An insulation resistance decrease detector 60 includes an AC voltage applying section 62 that applies AC voltage to the high voltage circuit 53 through a coupling capacitor 61. The AC voltage applying section 62 is electrically connected to the vehicle body 54. The coupling capacitor 61 includes a first terminal connected to a negative terminal of the battery 52, and a second terminal connected to the AC voltage applying section 62 with a sensing resistor 63. The detector 60 includes a voltage detecting section 64 that detects the voltage at the node between the coupling capacitor 61 and the sensing resistor 63. As the resistance value of the insulation resistor 55 is decreased, the voltage detected by the voltage detecting section 64 is lowered. When the detected voltage falls to or below a threshold value, the detector 60 determines that the resistance value of the insulation resistor 55 is decreased, that is, there is a leakage of electricity.

Japanese Laid-Open Patent Publication No. 2004-347372 discloses a coupling capacitor type leakage detector that achieves a highly accurate leakage detection performance despite a potential fluctuation in an on-vehicle circuit, which is insulated from the ground. As shown in FIG. 5, the leakage detector includes an on-vehicle circuit 70 that is insulated from the ground, a coupling capacitor 71, and an AC voltage applying circuit section 72. An AC voltage for detecting leakage from the AC voltage applying circuit section 72 is applied to a predetermined section of the on-vehicle circuit 70 through the coupling capacitor 71. Voltage changes at the node between the AC voltage applying circuit section 72 and the coupling capacitor 71 are compressed by a voltage compression circuit section 73. Then, a voltage signal having a necessary frequency component is extracted by a band-pass filter circuit 74. Thereafter, the extracted voltage signal is amplified by a voltage amplifier circuit 75 and sent to an impedance detection circuit 76. The impedance detection circuit 76 converts the output impedance of the voltage amplifier circuit 75 and sends it to a microcomputer 77. The microcomputer 77 converts an analog voltage signal sent from the impedance detection circuit 76 into a digital signal. If the magnitude of the digital signal is greater than a predetermined threshold value, the microcomputer 77 outputs a warning signal for warning of the occurrence of a leakage.

Battery-powered industrial vehicles such as forklifts and towing tractors currently use a battery of 48 V in general. In cases where a battery of a higher voltage is used or where a load driven by the electricity of a battery generates a great amount of heat and therefore is cooled not with air but with coolant, decrease in the resistance value of an insulation resistor needs to be detected to prevent electric shocks caused by a leakage. Further, in a case where a fuel cell is used as a power source, the fuel cell needs to be cooled by coolant. It is thus necessary to detect decrease in the resistance value of an insulation resistance.

The safety standards for battery-powered industrial vehicles require the following terms. No part of the vehicle frame or housing must electrically contact energized portions or be used as a part of an electric circuit. Therefore, when a hybrid vehicle or a fuel cell vehicle is built based on a battery-powered industrial vehicle, that is, for example, when a vehicle in which a conventional battery mounting portion is replaced by a hybrid system or a fuel cell system, the vehicle body cannot be used as a negative terminal, that is, the vehicle body cannot used as the ground.

The detector 60 shown in FIG. 4 is applied to a case where the vehicle body 54 is used as a negative terminal, that is, to a case where the negative terminal of an AC power supply is at the same potential as the vehicle body. The detector 60 thus cannot be applied to battery-powered industrial vehicles. Also, as in the case of the detector 60 shown in FIG. 4, the AC voltage applying circuit section 72 of the leakage detector according to the above publication shown in FIG. 5 is connected to the negative terminal of the high voltage battery 78 through the coupling capacitor 71, and the reference potential of the AC voltage applying circuit section 72 is at the same voltage as the vehicle body. Thus, the detector of FIG. 5 cannot be applied to battery-powered industrial vehicles.

### SUMMARY OF THE INVENTION

Accordingly, it is an objective of the present invention to provide an insulation resistance decrease detector that is capable of detecting a decrease in the resistance value of an insulation resistor, or the occurrence of a leakage, without equalizing the voltage of the vehicle body (vehicle frame) with a reference potential of an electric circuit.

To achieve the foregoing objective and in accordance with one aspect of the present invention, an insulation resistance decrease detector for an industrial vehicle is provided. The industrial vehicle has a high voltage circuit connected to a vehicle body through an insulation resistor. The high voltage circuit has a DC power supply. The detector includes a coupling capacitor, a sensing resistor, an AC voltage applying section, a voltage detecting section, and a determining section. The coupling capacitor has a first terminal and a second terminal. The first terminal of the coupling capacitor is connected to the vehicle body. The sensing resistor has a first terminal and a second terminal. The first terminal of the sensing resistor is connected to the second terminal of the coupling capacitor. The AC voltage applying section has a first terminal and a second terminal. The first terminal of the AC voltage applying section is connected to the second terminal of the sensing resistor. The second terminal of the AC voltage applying section is connected to the negative terminal of the DC power supply. The AC voltage applying section applies an AC voltage of a predetermined frequency to the vehicle body through the sensing resistor and the coupling capacitor. The voltage detecting section detects the voltage at a node between the sensing resistor and the coupling capacitor. The determining section determines that a resistance value of the insulation resistor has decreased when the level of voltage detected by the voltage detecting section becomes less than or equal to a predetermined level.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a circuit diagram showing an insulation resistance decrease detector according to one embodiment of the present invention and a high voltage circuit;

FIG. 2 is a circuit diagram of the detector shown in FIG. 1;

FIGS. 3A and 3B are each a diagram showing a voltage signal at a node in the circuit shown in FIG. 2;

FIG. 4 is a circuit diagram showing a conventional insulation resistance decrease detector and a high voltage circuit; and

FIG. 5 is a circuit diagram of a conventional leakage detector.

### DESCRIPTION OF THE PREFERRED EMBODIMENT

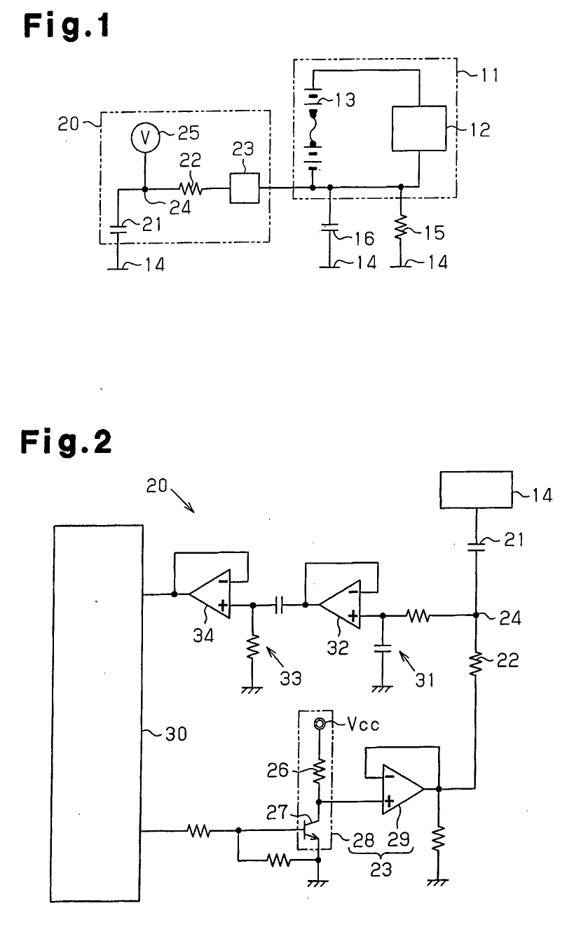

One embodiment of the present invention will now be described with reference to FIGS. 1 to 3.

As shown in FIG. 1, a high voltage circuit 11 includes a high voltage load 12 and a battery 13. The battery 13 functions as a DC power supply that supplies electricity to the high voltage load 12. The high voltage load 12 is, for example, a drive motor for drive wheels of an industrial vehicle or a hydraulic motor for a hydraulic circuit. The high voltage load 12 receives AC voltage via an inverter (not shown). The high voltage circuit 11 is connected to a body 14 of an industrial vehicle (vehicle frame) through an insulation resistor 15. Since the insulation resistor 15 has a resistance value of 2 to 3 MΩ, the high voltage circuit 11 is electrically insulated from the vehicle body 14. Reference numeral “16” denotes parasitic capacitance (wiring capacitance).

The insulation resistance decrease detector 20 includes a coupling capacitor 21, a sensing resistor 22, an AC voltage applying section 23, and a voltage detecting section 25. The coupling capacitor 21 has a first terminal connected to the vehicle body 14 and a second terminal connected to the sensing resistor 22. The second terminal of the sensing resistor 22 is connected to the first terminal (reference terminal) of the AC voltage applying section 23. The second terminal of the AC voltage applying section 23 is connected to the negative terminal of the battery 13 provided in the high voltage circuit 11. The AC voltage applying section 23 applies an AC voltage of a predetermined frequency to the vehicle body 14 through the sensing resistor 22 and the coupling capacitor 21. That is, the AC voltage applying section 23 is galvanically isolated from the vehicle body 14. The voltage detecting section 25 is connected to a node 24 between the sensing resistor 22 and the coupling capacitor 21, and detects the voltage at the node 24.

FIG. 2 is a circuit diagram showing a concrete construction of the detector 20. As shown in FIG. 2, the AC voltage applying section 23 includes a voltage amplifying section 28 and a voltage follower circuit (buffer circuit) 29. The voltage amplifying section 28 includes a DC power supply Vcc, a resistor 26, and a transistor 27, which are connected in series. The output terminal of the voltage follower circuit 29 is connected to the sensing resistor 22.

The detector 20 includes a microcomputer 30. The microcomputer 30 executes on/off control of the transistor 27 of the AC voltage applying section 23 at a predetermined interval. The microcomputer 30 functions as a determining section that determines that the resistance value of the insulation resistor 15 has been decreased when the detected voltage of the voltage detecting section 25 falls below a predetermined level. The microcomputer 30 executes on/off (switching) control of the transistor 27 at an interval that corresponds to a frequency that is significantly lower than the frequency of the alternating current supplied to the high voltage load 12, for example, at an interval that corresponds to several hertz.

The voltage detecting section 25 includes a low pass filter 31, a buffer circuit 32, a high pass filter 33, and a buffer circuit 34. The low pass filter 31, the buffer circuit 32, the high pass filter 33, and the buffer circuit 34 are connected in the listed order from the node 24 to the microcomputer 30. The voltage detecting section 25 outputs to the microcomputer 30 an analog voltage that corresponds to voltage changes at the node 24. That is, the voltage detecting section 25 includes the low pass filter 31 and the high pass filter 33 to extract, from voltage signals observed at the node 24, signals useful in the processes executed by the microcomputer 30. The microcomputer 30 converts analog signals sent from the voltage detecting section 25 into digital signals, and determines whether the level of the digital signals is less than or equal to a predetermined level.

An operation of the detector 20 will now be described.

The microcomputer 30 performs switching control of the transistor 27 of the AC voltage applying section 23 at a predetermined interval, and applies an AC voltage to the vehicle body 14 through the sensing resistor 22 and the coupling capacitor 21. In the present embodiment, AC voltage output by the AC voltage applying section 23 changes like rectangular waves that repeatedly has a high level and a low level with respect to a predetermined voltage (for example, zero bolts) at a predetermined interval. Through the coupling capacitor 21, the alternating current waveform is superimposed onto the vehicle body 14. The predetermined frequency of the AC voltage refers to a frequency that is significantly lower (for example, by three or four digit) than the frequency of potential fluctuation in the high voltage circuit 11, for example, than the frequency of the alternating current supplied to a high voltage load such as a motor.

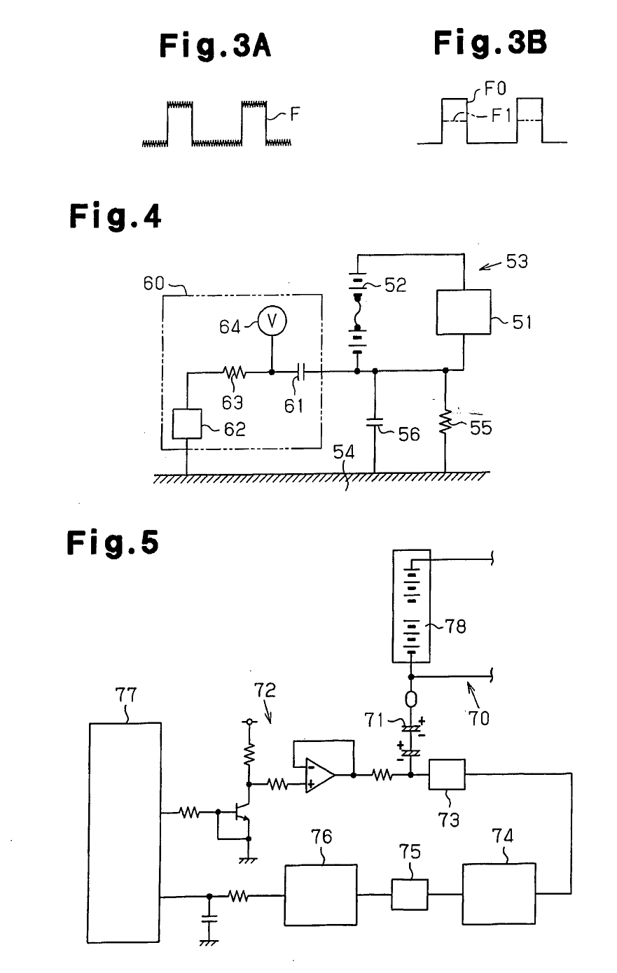

When there is no leakage in the high voltage circuit 11, the voltage at the node 24 changes in accordance with the AC voltage of rectangular waveform output by the AC voltage applying section 23. Also, noise component due to the potential fluctuation in the high voltage circuit 11 is superimposed onto the voltage at the node 24. The voltage at the node 24 becomes a signal F shown in FIG. 3A. The voltage detecting section 25 outputs a signal F0 of a rectangular waveform as indicated by solid line in FIG. 3B, from which unnecessary signal component (noise component) has been removed by the low pass filter 31 and the high pass filter 33.

When there is a leakage in the high voltage circuit 11, a current flows through the coupling capacitor 21, and the voltage at the node 24 is lowered. Then, the voltage detecting section 25 outputs a signal F1 as shown by two-dot chain line in FIG. 3B, of which the peak is lower than the signal F0 of a no-leakage state.

The microcomputer 30 monitors changes of the voltage at the node 24 by receiving the output from the voltage detecting section 25. When the detection voltage of the voltage detecting section 25 becomes lower than or equal to a predetermined level, the microcomputer 30 determines that the resistance value of the insulation resistor 15 has been decreased, and outputs a warning signal for warning of the occurrence of the leakage. As a result, an alarming device (not shown) is activated.

The present embodiment has the following advantages.

(1) The insulation resistance decrease detector 20 includes the coupling capacitor 21 connected to the vehicle body 14 and the AC voltage applying section 23, which is connected to the coupling capacitor 21 via the sensing resistor 22 and to the negative terminal of the battery 13 provided in the high voltage circuit 11. The AC voltage applying section 23 applies an alternating current of a predetermined frequency to the vehicle body 14. The insulation resistance decrease detector 20 includes the voltage detecting section 25, which detects the voltage at the node 24 between the sensing resistor 22 and the coupling capacitor 21, and the microcomputer 30, which determines that the resistance value of the insulation resistor 15 has been decreased when the detection voltage of the voltage detecting section 25 becomes less than or equal to the predetermined level. Therefore, the potential of the vehicle body (vehicle frame) 14 does not become equal to that of the first terminal (reference terminal) of the AC voltage applying section 23. In other words, decrease in the resistance value of the insulation resistor 15, or the occurrence of a leakage, can be detected in a state where the AC voltage applying section 23 is galvanically isolated from the vehicle body 14.

(2) The voltage detecting section 25 includes the low pass filter 31, the buffer circuit 32, the high pass filter 33, and the buffer circuit 34. The low pass filter 31, the buffer circuit 32, the high pass filter 33, and the buffer circuit 34 are connected in the listed order from the node 24 to the microcomputer 30. Therefore, from the voltage signals observed at the node 24, only a signal useful for determining decrease in the resistance value of the insulation resistor 15, that is, the occurrence of a leakage, is extracted. Thus, compared to a case where the microcomputer 30 receives a voltage signal which has not been passed through a filter, the microcomputer 30 accurately determines decrease in the resistance value of the insulation resistor 15, that is, determines the occurrence of a leakage. Also, compared to a case where a band-pass filter is provided, the band of frequencies to be removed is easily set.

(3) In an industrial vehicle that uses cooling coolant (for example, an industrial vehicle that uses coolant to cool a motor or a DC/DC converter, or an industrial vehicle having a power supply that uses coolant to cool a fuel cell), a leakage can possibly lead to electric shocks through the coolant. To suppress such electric shocks, the occurrence of a leakage or a condition in which a leakage is likely to occur need to be detected in an early stage. Since the detector 20 of the present embodiment easily detects decrease in the resistance value of the insulation resistor 15 as described above, a leakage can be detected at an early stage.

(4) By applying an alternating current waveform to the vehicle body (vehicle frame) 14 in a superimposing manner, decrease in the resistance value of the insulation resistor 15 can be detected in a vehicle that does not use the vehicle body (vehicle frame) 14 as a part of an electric circuit, for example, in a vehicle that has a fuel cell system in a conventional battery mounting portion instead of the battery 13.

The present invention is not limited to the above embodiment, but may be modified as follows.

The DC power supply is not limited to a battery, but may be, for example, a fuel cell or a capacitor of a large capacitance.

The insulation resistance decrease detector 20 of the present invention may be mounted on an industrial vehicle that air-cools the high voltage load 12 and uses a battery of which the voltage is higher than 48 V.

In the illustrated embodiment, the low pass filter 31 and the high pass filter 33 are provided to remove signals unnecessary for removing detecting decrease in the resistance value of the insulation resistor 15. Instead of this configuration, for example, a configuration having a band-pass filter or only the low pass filter 31 may be used.

The AC voltage applying section 23 is not limited to the configuration in which the transistor 27 (switching element) is subjected to switching control at a predetermined interval so as to output rectangular waves. For example, the AC voltage applying section 23 may include a sinusoidal oscillator circuit or another oscillator circuit.

The industrial vehicle to which the present invention is applied is not limited to, for example, a forklift or a towing tractor, but may be a loading shovel or a vehicle with an aerial work platform.

What is claimed is:

1. An insulation resistance decrease detector for an industrial vehicle, the industrial vehicle having a high voltage circuit connected to a vehicle body through an insulation resistor, the high voltage circuit having a DC power supply, the detector comprising:
a coupling capacitor having a first terminal and a second terminal, the first terminal of the coupling capacitor being connected to the vehicle body;
a sensing resistor having a first terminal and a second terminal, the first terminal of the sensing resistor being connected to the second terminal of the coupling capacitor;
an AC voltage applying section having a first terminal and a second terminal, the first terminal of the AC voltage applying section being connected to the second terminal of the sensing resistor, and the second terminal of the AC voltage applying section being connected to the negative terminal of the DC power supply, wherein the AC voltage applying section applies an AC voltage of a predetermined frequency to the vehicle body through the sensing resistor and the coupling capacitor;
a voltage detecting section that detects the voltage at a node between the sensing resistor and the coupling capacitor; and
a determining section that determines that a resistance value of the insulation resistor has decreased when the level of voltage detected by the voltage detecting section becomes less than or equal to a predetermined level.

2. The detector according to claim 1, wherein the industrial vehicle uses coolant to cool the DC power supply or a load that receives electricity from the DC power supply.

3. The detector according to claim 1, wherein the DC power supply includes a fuel cell.

4. The detector according to claim 1, wherein the industrial vehicle is a hybrid car.

5. The detector according to claim 1, wherein the voltage detecting section has a filter for removing a noise component from the detected voltage.

6. The detector according to claim 5, wherein the filter includes a low pass filter and a high pass filter.
